(19) United States
(12) Patent Application Publication
(10) Pub. No.: US 2002/0096712 A1
(43) Pub. Date: Jul. 25, 2002

(54) Semiconductor device and method for manufacturing the same

(76) Inventor: Katsuhiko Fukasaku, Tokyo (JP)

Correspondence Address: McGinn & Gibb, PLLC, 8321 Old Courthouse Road, Suite 200, Vienna, VA, 22182-3817, US

(21) Appl. No.: 10/050,165

(22) Filed: Jan. 18, 2002

(30) Foreign Application Priority Data
Jan. 19, 2001 (JP) 2001-11592

(51) Int. Cl. H01L 31/119; H01L 31/113; H01L 31/062; H01L 29/94; H01L 29/76

(52) U.S. Cl. 257/333

(57) ABSTRACT

A semiconductor device of the invention integrates a plurality of types of MOSFETs formed on its substrate in such a configuration that a gate insulator film 51 of a core-purpose MOSFET is thinner than a gate insulator film 12 of an I/O-purpose MOSFET and also a poly-silicon film 8 which is to act as a gate electrode of the core-purpose MOSFET is thinner in thickness than a poly-silicon 13 which is to act as a gate electrode of the I/O-purpose MOSFET.

### BACKGROUND OF THE INVENTION

1. Field of the Invention

The present invention relates to a semiconductor device and a method for manufacturing the same and, more particularly to, a semiconductor device that has a plurality of types of MOSFETs (Metal Oxide Semiconductor Field Effect Transistors) in a mixed manner on its substrate and a method for manufacturing the same.

2. Description of the Related Art

Conventionally, as a semiconductor device that has a plurality of types of MOSFETs as mixed on its substrate, there has been available such an NMOSFET device in which there is a difference in gate insulator film thickness between an N-channel MOSFET used as the core and an N-channel MOSFET used for input/output operations.

The following will describe how to manufacture this NMOSFET device with reference to FIGS. 5-6.

First, as shown in FIG. 5A, an element isolation region 2 is formed in a P-type silicon substrate 1 and then a P-type impurity such as boron is implanted into a core-purpose NMOSFET formation region A to thereby form a core-purpose P-type well (core-purpose P-well) 3, while a P-type impurity such as boron is implanted into an I/O-purpose NMOSFET formation region B to thereby form an I/O-purpose P-type well (I/O-purpose P-well) 4. Then, the substrate is oxidized thermally to form a gate insulator film 5 made of an oxidized silicon nitride etc., on which is formed a photo-resist (PR) mask 6 except on the core-purpose NMOSFET formation region.

Next, the gate insulator film 5 present on the core-purpose NMOSFET formation region is removed by wet etching to then remove the PR mask 6, which is followed by formation of a core-purpose gate insulator film 7 on the core-purpose NMOSFET formation region as shown in FIG. 5B. In this step, although the gate insulator film 5 on the I/O-purpose NMOSFET formation region is oxidized additionally, its film thickness is increased only slightly, thus having no influence on the device properties.

Next, as shown in FIG. 5C, on thus formed surface of the substrate is deposited a poly-silicon film 8 which is to act as a gate electrode. Then, as shown in FIG. 5D, on the poly-silicon film 8 is formed a PR mask 9, which is used in patterning to form a gate electrode thereon by dry etching. Finally, the PR mask 9 is removed to provide an NMOSFET device shown in FIG. 6.

In this prior art NMOSFET device, to form a Lightly Doped Drain (LDD) region, the same gate electrode is used as a mask for both the core-purpose MOSFET and the I/O-purpose MOSFET, an energy implanted to the LDD region is restricted by thick gate electrode. Thus making it impossible to dope an impurity deep, problematically.

Also, as for the prior art NMOSFET device, it has been necessary to enhance the performance of a MOSFET by scaling in order to realize an ultra-fine device having such a reduced gate length of about 0.1 μm. Here, though a thinnerizalion of the gate electrode is pushed, a resultant higher aspect ratio between a gate length and a gate thickness restricts the processibility of gate etching, problematically. Also, to improve the performance of an MOSFET, it is necessary to suppress the depleting below a gate region and hence to enhance an impurity concentration in a gate electrode, which in turn requires the scaling of the thickness of the gate electrode.

Also, in the prior art NMOSFET device, a high-performance MOSFET may not be formed alone but needs to be formed as mixed with an I/O-purpose MOSFET used in a peripheral I/O circuit. In contrast to a core-purpose MOSFET used as the MPU driven on a low voltage and a low power dissipation for all-time circuit operations, the I/O-purpose MOSFET is used in a circuit driven in I/O operations for a short service time and so need not be driven on a low voltage, so that the I/O-purpose MOSFET driven on a high voltage and the high-performance core-purpose MOSFET driven on a low voltage must be mixed in the same device, problematically.

Also, the I/O-purpose MOSFET need not be scaled so much as the high-performance MOSFET, so that generally a device used in the previous generation has been integrated as it is in a mixed manner with a core-purpose MOSFET. This brings about such a problem that since a core-purpose MOSFET which needs to be scaled and a previous-generation I/O-purpose MOSFET are present in a mixed manner, these transistors must have thick gate electrode from a viewpoint of reliabilities, so that a device containing multi-oxide transistors with different thickness values of the gate insulator film must employ a multi-gate electrode thickness configuration.

### SUMMARY OF THE INVENTION

In view of the above, it is an object of the present invention to provide such a semiconductor device containing a plurality of types of transistors with different thickness values of the gate insulator film thereof that is capable of suppressing the depleting below a gate electrode of the transistor with a thinner gate insulator film, that is capable of forming an LDD deep enough to suppress the occurrence of a hot carrier in the transistor with a thicker gate insulator film, and also that is capable of increasing a process margin of gate processing during device manufacture, and a method for manufacturing such a semiconductor device.

In order to solve above mentioned problem, present invention provide a following semiconductor device and manufacturing method thereof. A semiconductor device according to present invention comprising a plurality of types of transistors having different gate insulator film in their thickness value, said plurality of types of transistors having different thickness values of gate electrode in correspondence to the thickness values of the gate insulator film thereof.

Moreover, the semiconductor device having said plurality of types of transistors consists of a plurality of types of MOSFETs formed on a substrate.

Moreover, the semiconductor device having said MOSFET including a core-purpose MOSFET and an I/O-purpose MOSFET; and said core-purpose MOSFET has smaller thickness of the gate insulator film than that of said I/O-purpose MOSFET and the also has a smaller thickness of the gate electrode than that of said I/O-purpose MOSFET.

Moreover, a method for manufacturing a semiconductor device according to present invention integrating therein a plurality of types of transistors having different gate insulator film in their thickness value in which gate electrodes thereof are different in thickness from each other corresponding to the thickness of the gate insulator films thereof, comprising a step of, when depositing respective gate electrode materials of said plurality of types of transistors, providing said gate electrode materials in different amounts of depositing material corresponding to the thickness of the respective gate insulator films.

Moreover, the semiconductor device manufacturing method, wherein said depositing amounts are set by changing the number of depositing said gate electrode materials.

Moreover, the semiconductor device manufacturing method, wherein said gate electrode material depositing amounts are first set on the basis of said thicker gate insulator film and then increased or decreased by selectively removing said gate electrode materials.

### BRIEF DESCRIPTION OF THE DRAWINGS

FIG. 1 is a process diagram for showing a method for manufacturing an NMOSFET device according to a first embodiment of the present invention;

FIG. 2 is a continued process diagram for showing a method for manufacturing the NMOSFET device according to the first embodiment of the present invention;

FIG. 3 is a further continued process diagram for showing the method for manufacturing the NMOSFET device according to the first embodiment of the present invention;

FIG. 4 is a process diagram for showing a method for manufacturing an NMOSFET device according to a second embodiment of the present invention;

FIG. 5 is a process diagram for showing a method for manufacturing a prior art NMOSFET device; and

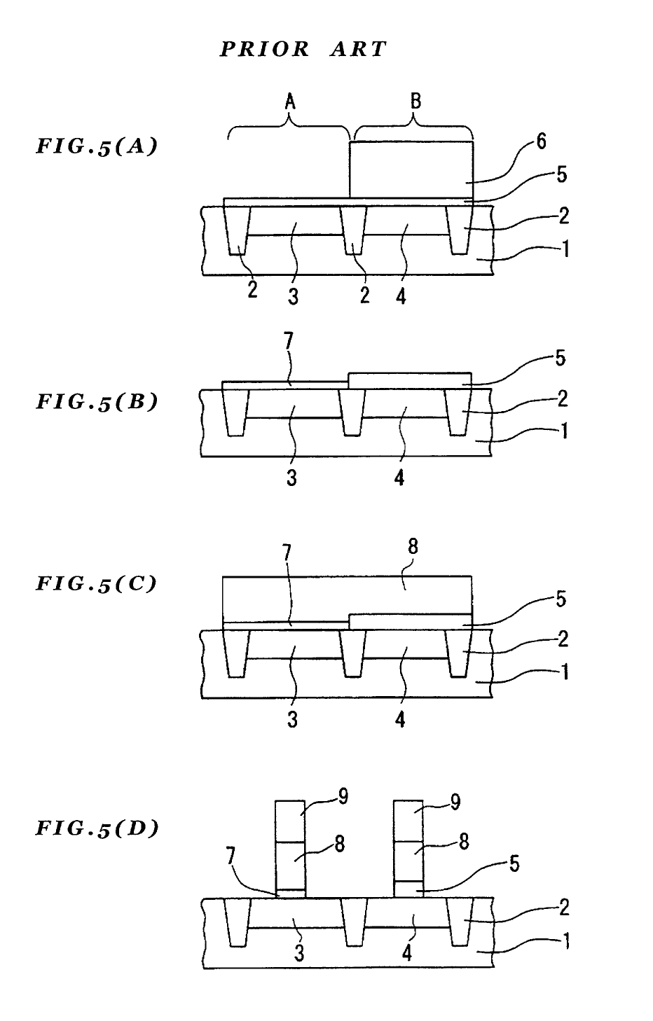

FIG. 6 is a continued process diagram for showing the method for manufacturing the prior art NMOSFET.

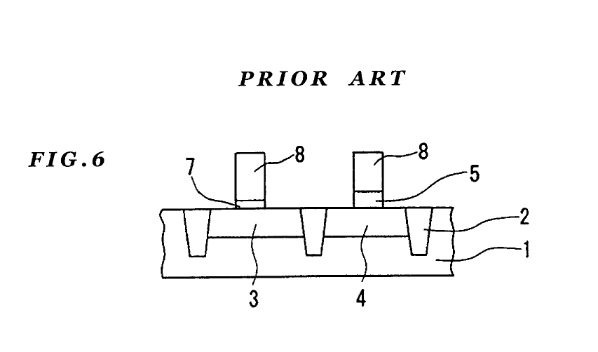

### DESCRIPTION OF THE PREFERRED EMBODIMENTS

The following will describe embodiments of a semiconductor device and a method for manufacturing the same according to the present invention with reference to the drawings.

### First Embodiment

A semiconductor device according to the first embodiment of the present invention comprising on its substrate a plurality of types of MOSFETs having different thickness values of gate insulator film thereof will be described below with reference to an example where a core-purpose N-channel MOSFET and an I/O-purpose N-channel MOSFET are different in thickness of the gate insulator film thereof.

This NMOSFET device is based on the 70-nm design rule and has such a configuration that as the core-purpose NMOSFET is used an N-channel MOSFET driven on a supply voltage of 1.0V and as the I/O-purpose NMOSFET is used an N-channel MOSFET driven on a supply voltage of 3.3V.

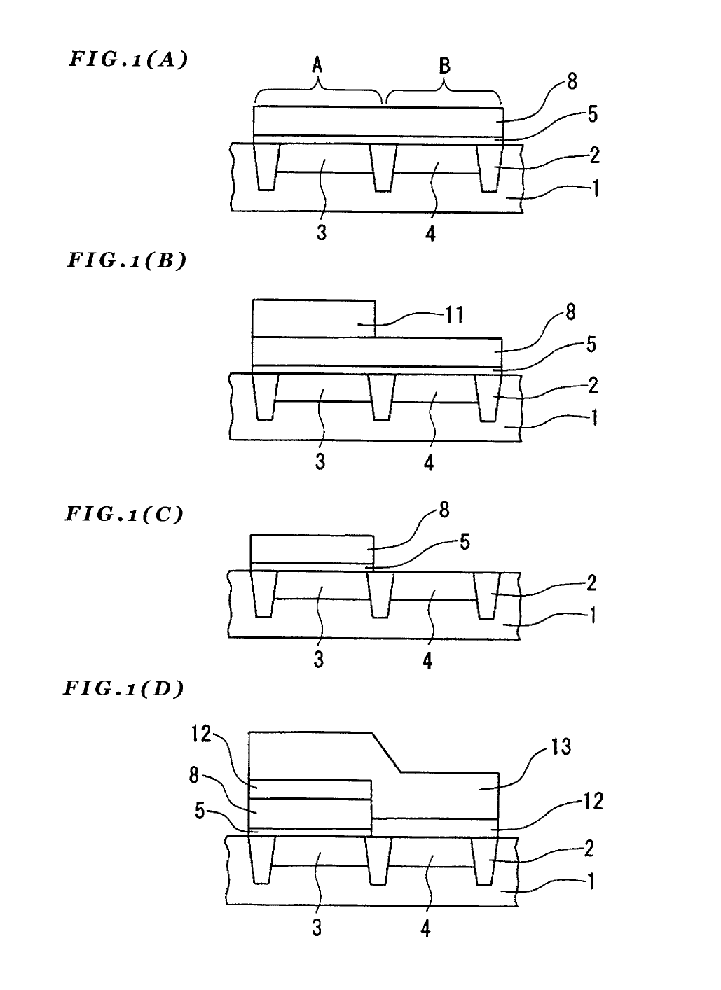

A method for manufacturing the NMOSFET device according to this embodiment is described with reference to FIGS. 1-3.

First, as shown in FIG. 1A, the prior art process is used to form an element isolation region 2 in a P-type silicon substrate, then implant into a core-purpose NMOSFET formation region A such a P-type impurity as boron (B) at a density of 2×10¹³/cm² and at an energy level of 150 keV and also at a density of 5×10¹²/cm² and at an energy level of 15 keV to thereby form a core-purpose P-well 3, and then implant a P-type impurity such as boron at a density of 1×10¹²/cm² and at an energy level of 30 keV into an I/O-purpose NMOSFET formation region B to thereby form an I/O-purpose P-well 4.

Next, on these is formed such a gate insulator film 5 of the core-purpose NMOSFET that is made of oxidized silicon nitride to a thickness of 15 Å using the Rapid Thermal Process (RTP) method, on which is in turn deposited using Chemical Vapor Deposition (CVD) such a poly-silicon film 8 to a thickness of 100 nm that is to act as a gate electrode of the core-purpose NMOSFET.

Next, as shown in FIG. 1B, using exposure processing, on this poly-silicon film 8 is formed a PR mask 11 and then, as shown in FIG. 1C, the poly-silicon film 8 of the I/O-purpose NMOSFET formation region B is removed by dry etching. In this step, the gate insulator film 5 of the I/O-purpose NMOSFET formation region B is also removed simultaneously. Afterward, the PR mask 11 is removed by wet etching.

Next, as shown in FIG. 1D, thermal oxidation is carried out to form such a gate insulator film 12 of the I/O-purpose NMOSFET that is made of silicon oxide etc. to a thickness of 70 Å everywhere on the substrate surface. Then, thoroughly on the substrate surface is deposited by CVD a poly-silicon film 13 which is to act as a gate electrode of the I/O-purpose NMOSFET to a thickness of 150 nm.

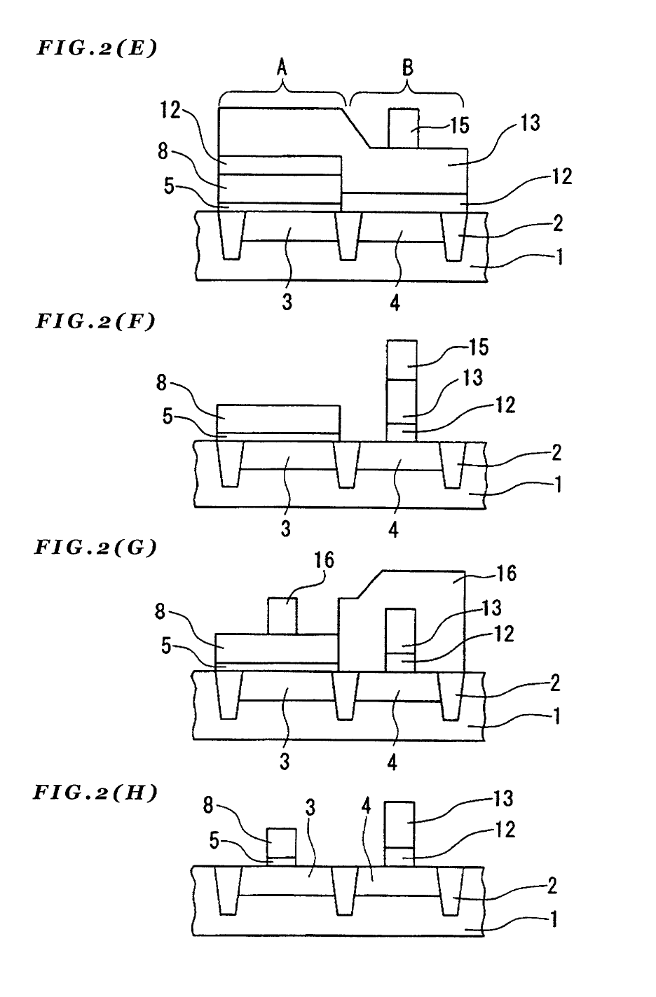

Next, as shown in FIG. 2E, exposure processing is carried out to form a PR mask 15 on the poly-silicon film 13 of the I/O-purpose NMOSFET formation region B and then, as shown in FIG. 2F, the poly-silicon film 13 at the top layer of the core-purpose NMOSFET formation region A is dry-etched and, at the same time, the gate insulator film 12 and the ply-silicon film 13 of the I/O-purpose NMOSFET formation region B are patterned so as to form a gate.

This PR mask 15 is removed by wet etching, then, as shown in FIG. 2G, exposure processing is carried out to form a PR mask 16, and then, as shown in FIG. 2H, the gate insulator film 5 and the poly-silicon film 8 of the core-purpose NMOSFET formation region A are patterned so as to form a gate. Afterward, the PR mask 16 is removed by wet etching.

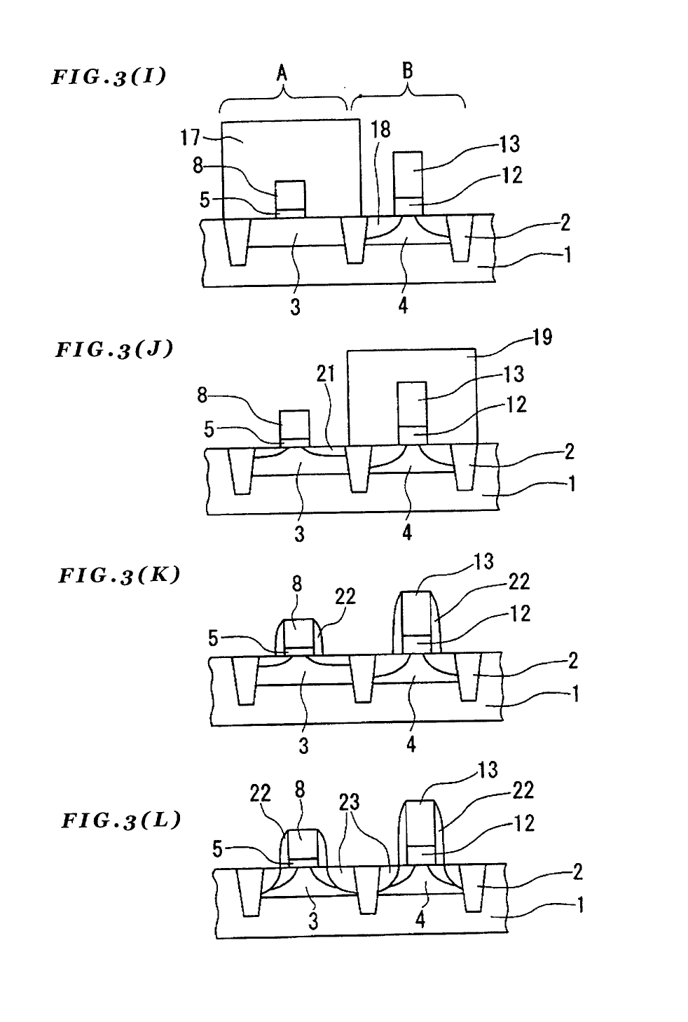

Next, as shown in FIG. 3I, exposure processing is carried out to form a PR mask 17 on the core-purpose NMOSFET formation region A and, then, an N-type impurity such as phosphorus (P) is implanted into the I/O-purpose P-well 4 at a density of 2×10¹³/cm² and an energy level of 30 keV to form an LDD region 18 to then remove the PR mask 17 by wet etching.

Next, as shown in FIG. 3J, exposure processing is carried out to form a PR mask 19 on the I/O-purpose NMOSFET formation region B, then an N-type impurity such as arsenic (As) is implanted into the core-purpose P-well 3 at a density of 5×10¹⁴/cm² and at an energy level of 2.5 keV to thereby form an LDD region 21 to remove the PR mask 19 by wet etching.

Next, as shown in FIG. 3K, a TEOS-NSG (Tetra Ethyl Ortho-Silicate Nondoped Silicate Glass) film is deposited by CVD to a thickness of 80 nm to then form side walls 22 by dry etching.

Next, as shown in FIG. 3L, an N-type impurity such as arsenic (As) is implanted at a density of 5×10¹⁵/cm² and an energy level of 30 keV to thereby form source/drain (S/D) regions 23.

The following steps as well as those for P-channel transistors are the same as the steps by the prior art.

From a viewpoint of facilitating gate etching, the above-mentioned NMOSFET should preferably have a smaller aspect ratio between a gate length and a gate electrode thickness, so that preferably a high-performance MOSFET with a reduced gate length has also a reduced gate electrode thickness to improve the processibility and increase the process margin. From a viewpoint of facilitating the designing of the I/O-purpose NMOSFET, on the other hand, although a smaller thickness of a gate electrode enables ion implantation into an LDD by use of the gate electrode as a mask, an impurity exists directly below the gate electrode, so that an energy level at which ions are implanted to form an LDD region must be lowered. Thus formed shallow LDD region, however, has a stronger electric field at its drain ends and so problematically gives rise to hot carriers, thus suffering from a deteriorated device reliability. To guard against this, the gate must be large in thickness in the I/O-purpose NMOSFET.

As can be seen from the above, in a MOSFET device which comprises in a mixed manner the inventive core-purpose NMOSFET and I/O-purpose NMOSFET having different thickness values of gate insulator film thereof, the core-purpose NMOSFET can have a thinner gate electrode than the I/O-purpose one to thereby suppress depletion below the gate electrode of this core-purpose NMOSFET, thus increasing the process margin of gate etching in processing.

Also, since the I/O-purpose NMOSFET can have a thicker gate electrode, the gate can be used as a mask to thereby form the LDD region 18 deep in order to suppress the occurrence of hot carriers, thus optimizing the design in correspondence to the high-voltage reliabilities.

Also, to suppress such depletion below the gate that is caused by a smaller thickness of the gate insulator films 5 and 12 needs, when forming the SD region 23 with a thinner gate of the core-purpose NMOSFET, an impurity can be implanted into the gate electrode to suppress the depletion, thus having an effect of increasing the impurity concentration.

### Second Embodiment

A semiconductor device according to the second embodiment of the present invention is an NMOSFET device that integrates on its substrate a plurality of types of MOSFETs having different thickness values of gate insulator film, in which the gate insulator film thickness is different between a core-purpose N-channel MOSFET and an I/O-purpose N-channel MOSFET.

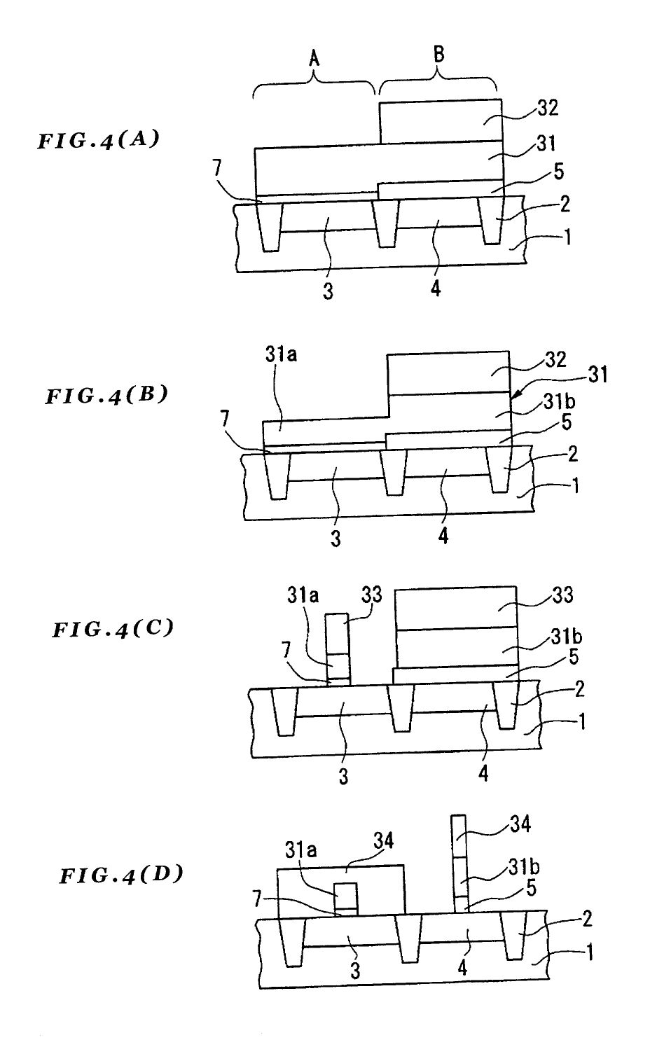

The following will describe a method for manufacturing this NMOSFET device with reference to FIG. 4.

First, as shown in FIG. 4A, a prior art manufacturing process is used to form the gate insulator films 5 and 7 having different film thickness values and then deposit thereon a poly-silicon film 31 to a thickness of 150 nm which is to act as an I/O-purpose gate electrode. Then, exposure processing is carried out to form a PR mask 32 on this poly-silicon film 31 of the I/O-purpose NMOSFET formation region B.

Next, as shown in FIG. 4B, the poly-silicon film 31 of the core-purpose NMOSFET formation region A is dry-etched by 50 nm. This step gives a step of 50 nm between a poly-silicon film 31a of the core-purpose NMOSFET formation region A and a poly-silicon film 31b of the I/O-purpose NMOSFET formation region B. Afterward, the PR mask 32 is removed by wet etching.

Next, as shown in FIG. 4C, exposing processing is carried out to form a PR mask 33 on the poly-silicon films 31a and 31b to then form by patterning a core-purpose gate electrode in the poly-silicon film 31a by dry etching. Afterward, the PR mask 33 is removed by wet etching.

Next, as shown in FIG. 4D, on these is formed a PR mask 34 by exposure processing to then form by patterning the I/O-purpose gate electrode in the poly-silicon film 31b by dry etching.

This PR mask 34 is removed by wet etching, which is followed by the process in accordance with the NMOSFET manufacturing method of the first embodiment.

This NMOSFET manufacturing method according to the second embodiment has almost the same effects as those by that according to the first embodiment.

Moreover, the second embodiment needs to deposit the poly-silicon film 31 only once, thus enabling simplifying the manufacturing process.

Although the embodiments of the semiconductor device and its manufacturing method according to the present invention have been described with reference to the drawings, the specific configuration is not limited thereto; changes and modifications in design are possible without departing the gist of the present invention.

As mentioned above, by the semiconductor device of the present invention integrating therein a plurality of types of transistors that has different thickness values of gate insulator film thereof in such a manner that the gate electrode thickness thereof is respectively changed in correspondence to the thickness of the gate insulator film thereof, it is possible to suppress depletion below the gate of the transistor with the thinner gate film and also to have the thicker gate electrode of the transistor with the thicker gate insulator film, so that when this gate is used as a mask to form an LDD region for the purpose of suppressing the occurrence of hot carriers, this LDD region can be formed deep. This feature will optimize the design in correspondence to the reliabilities at the time of high-voltage driving.

By the semiconductor manufacturing method of the present invention, when depositing gate electrode materials for a plurality of corresponding types of transistors, the amounts of depositing those materials can be increased or decreased corresponding to the thickness of the gate insulator films, so that it is possible to easily and inexpensively manufacture a semiconductor device in which the thickness of the gate electrodes of a plurality of types of transistors integrated therein is changed corresponding to the thickness of the gate insulator films.

Also, the present invention makes it possible to increase the process margin of gate etching in processing.

The invention may be embodied in other specific forms without departing from the spirit or essential characteristic thereof. The present embodiments are therefore to be considered in all respects as illustrative and not restrictive, the scope of the invention being indicated by the appended Claims rather than by the foregoing description and all changes which come within the meaning and range of equivalency of the Claims are therefore intended to be embraced therein.

The entire disclosure of Japanese Patent Application No. 2001-11592 (Filed on Jan. 19^{th}, 2001) including specification, claims, drawings and summary are incorporated herein by reference in its entirety.

What is claimed is:

1. A semiconductor device comprising a plurality of types of transistors having different gate insulator film in their thickness value, said plurality of types of transistors having different thickness values of gate electrode in correspondence to the thickness values of the gate insulator film thereof.

2. The semiconductor device according to claim 1, wherein said plurality of types of transistors consists of a plurality of types of MOSFETs formed on a substrate.

3. The semiconductor according to claim 2, wherein:
said MOSFET including a core-purpose MOSFET and an I/O-purpose MOSFET; and
said core-purpose MOSFET has smaller thickness of the gate insulator film than that of said I/O-purpose MOSFET and the also has a smaller thickness of the gate electrode than that of said I/O-purpose MOSFET.

4. A method for manufacturing a semiconductor device integrating therein a plurality of types of transistors having different gate insulator film in their thickness value in which gate electrodes thereof are different in thickness from each other corresponding to the thickness of the gate insulator films thereof, comprising a step of, when depositing respective gate electrode materials of said plurality of types of transistors, providing said gate electrode materials in different amounts of depositing material corresponding to the thickness of the respective gate insulator films.

5. The semiconductor device manufacturing method according to claim 4, wherein said depositing amounts are set by changing the number of depositing said gate electrode materials.

6. The semiconductor device manufacturing method according to claim 4, wherein said gate electrode material depositing amounts are first set on the basis of said thicker gate insulator film and then increased or decreased by selectively removing said gate electrode materials.
